(19) United States
(12) Patent Application Publication
(10) Pub. No.: US 2010/0215464 A1
(43) Pub. Date: Aug. 26, 2010

(54) AUTOMATIC PRODUCT DISTRIBUTION SYSTEM AND A METHOD THEREOF

(75) Inventor: CHIANG-LUAN LIU, TAIPEI COUNTY 237 (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES INC., TAOYUAN COUNTY 333 (TW)

(21) Appl. No.: 12/542,190

(22) Filed: Aug. 17, 2009

(30) Foreign Application Priority Data
Feb. 23, 2009 (TW) 98105598

(51) Int. Cl. H01L 21/67; B65G 65/00; B65G 65/30; H01L 21/00

(52) U.S. Cl. 414/404; 414/811

(57) ABSTRACT

An automatic product distribution system is disclosed. The product distribution system includes a distribution platform and a transportation platform. The distribution platform is used for distributing the products in the main storage unit into the secondary storage unit. The transportation platform is used for transporting the main storage unit and the secondary storage unit. The transportation platform transports the main storage unit and the secondary storage unit to the distribution platform and the distribution platform executes a distribution operation. After the distribution operation is finished, the transportation platform transports the secondary storage unit out of the distribution platform and transports another secondary storage unit to the distribution platform so that the distribution platform executes a distribution operation again. Thereby, the distribution platform can continuously execute the distribution operations.

### BACKGROUND OF THE INVENTION

1. Field of the Invention

The present invention relates to a product distribution system and a method thereof, in particular, the present invention relates to an automatic product distribution system and a method thereof that is applied to the semiconductor field.

2. Description of Related Art

During the semiconductor wafer manufacturing process, a variety of manufacturing processes are required for various different wafers to be produced into a specific product. One wafer storage cassette can receive a plurality of wafers. When these wafers stored in the wafer storage cassette needs to be processed by different manufacturing processes, a wafer distribution process is required to distribute the wafers into different wafer storage cassette. When the wafers in the wafer storage cassettes cannot be efficiently distributed, the equipments cannot evenly access and use the wafers so that the product quantity is low.

Reference is made to FIGS. 1A and 1B. FIG. 1A is a prior art schematic diagram of the wafer storage cassette being loaded. FIG. 1B is a prior art schematic diagram of the wafer storage cassette being uploaded. When a loading operation is performed, a main wafer storage cassette 1a stored with wafers can not perform the loading operation to distribute the wafers in the main wafer storage cassette 1a into each of the other wafer storage cassettes 2a until all other wafer storage cassettes 2a have arrived (as shown in FIG. 1A, the arrow in FIG. 1A shows the wafer distribution operation). When an unloading operation is performed, the main wafer storage cassette 1a can not perform the unloading operation to move the wafers in the main wafer storage cassette 1a and all other wafer storage cassettes 2a until all other wafer storage cassettes 2a have arrived (as shown in FIG. 1B, the black arrow in FIG. 1B shows the wafer unloading operation).

The attribution process of the prior art in the semiconductor field has the following drawbacks.

1. The main wafer storage cassette 1 a can not perform the loading operation until all other wafer storage cassettes 2a have arrived. Therefore, when one of the other wafer storage cassettes 2a has not arrived, the main wafer storage cassette 1a is thus idle and not performing the loading operation, therefore the wafer manufacturing process is affected and the production quantity is low.

2. When the unloading operation is performed, the main wafer storage cassette 1a can not perform the unloading operation until all other wafer storage cassettes 2a have arrived. Similarly, it takes an extended length of time and thereby the time for producing wafer becomes longer.

### SUMMARY OF THE INVENTION

One particular aspect of the present invention is to provide an automatic product distribution system and a method thereof that can continuously perform distribution operation so to reduce the idle time.

The automatic product distribution system is applied to product distribution in the semiconductor foundry so as to distribute products in a main storage unit to a secondary storage unit. The product distribution system includes a distribution platform for temporarily being placed with the main storage unit and the secondary storage unit, and a transportation platform for moving the main storage unit and the secondary storage unit. The distribution platform has a distribution unit, and the distribution unit distributes the products in the main storage unit into the secondary storage unit. After the distribution unit executes a distribution operation, the transportation platform moves the secondary storage unit out of the distribution platform.

The present invention also provides a product distribution method that is applied to the automatic product distribution system. The product distribution method includes the following steps. The main storage unit is transported to the distribution platform. The secondary storage unit is transported to the distribution platform and the distribution unit executes a distribution operation. After the distribution operation is finished, if the products in the main storage unit are not all distributed, then the secondary storage unit is transported out of the distribution platform and another secondary storage unit is transported to the distribution platform, and the distribution unit executes the distribution operation again. If the products in the main storage unit are all distributed, then the transportation platform transports the main storage unit and the secondary storage unit out of the distribution platform.

The automatic product distribution system and a method thereof of the present invention have the following characteristics. The automatic product distribution system and the product distribution method can reduce the time of the main storage unit and the secondary storage unit being idle on the distribution platform and thereby improve the production speed. Furthermore, for the automatic product distribution system and the product distribution method, the distribution platform can execute the distribution operation when one main storage unit and one secondary storage unit are temporarily placed on the distribution platform. It does not need to transport all of the secondary storage units to the distribution platform. Therefore, the present invention can continuously perform the distribution operation, and the idle problem is solved.

For further understanding of the present invention, reference is made to the following detailed description illustrating the embodiments and examples of the present invention. The description is for illustrative purpose only and is not intended to limit the scope of the claim.

### BRIEF DESCRIPTION OF THE DRAWINGS

FIG. 1A is a schematic diagram of the wafer storage cassette being loaded of the prior art;

FIG. 1B is a schematic diagram of the wafer storage cassette of being uploaded of the prior art;

FIG. 2 is a schematic diagram of the automatic product distribution system of the present invention;

FIG. 3A-3G are schematic diagrams of the usage statuses of the automatic product distribution system of the present invention; and

FIG. 4 is a flow chart of the product distribution method of the present invention.

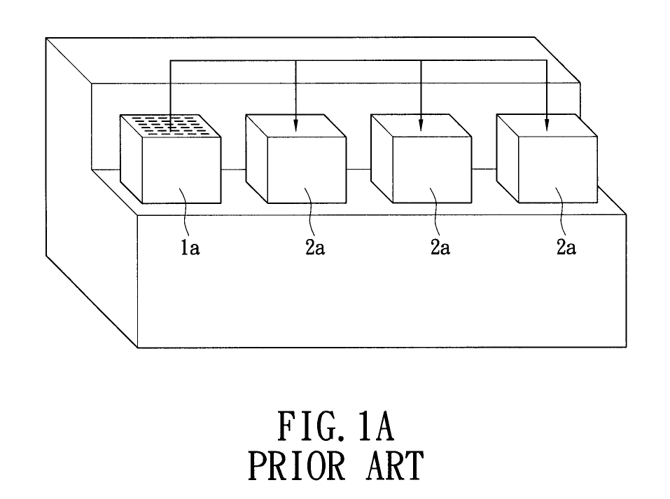

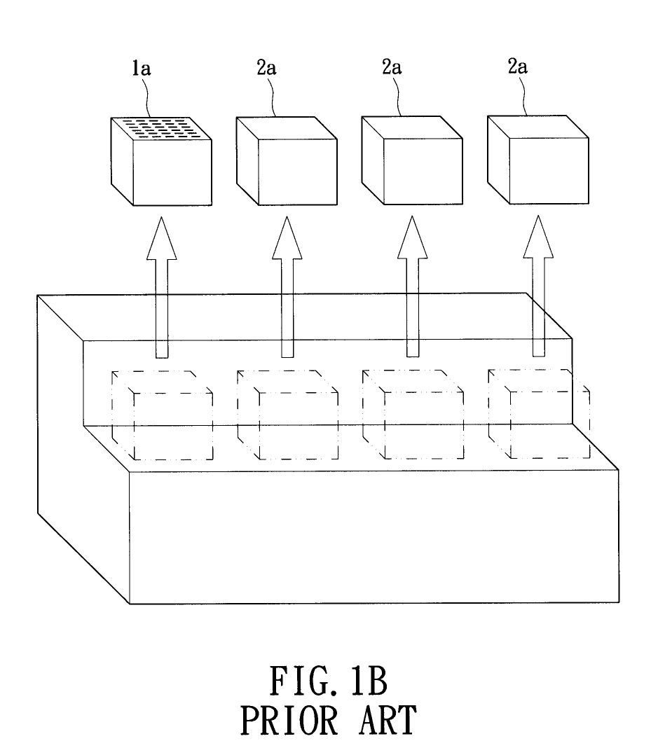

### DETAILED DESCRIPTION OF THE PREFERRED EMBODIMENTS

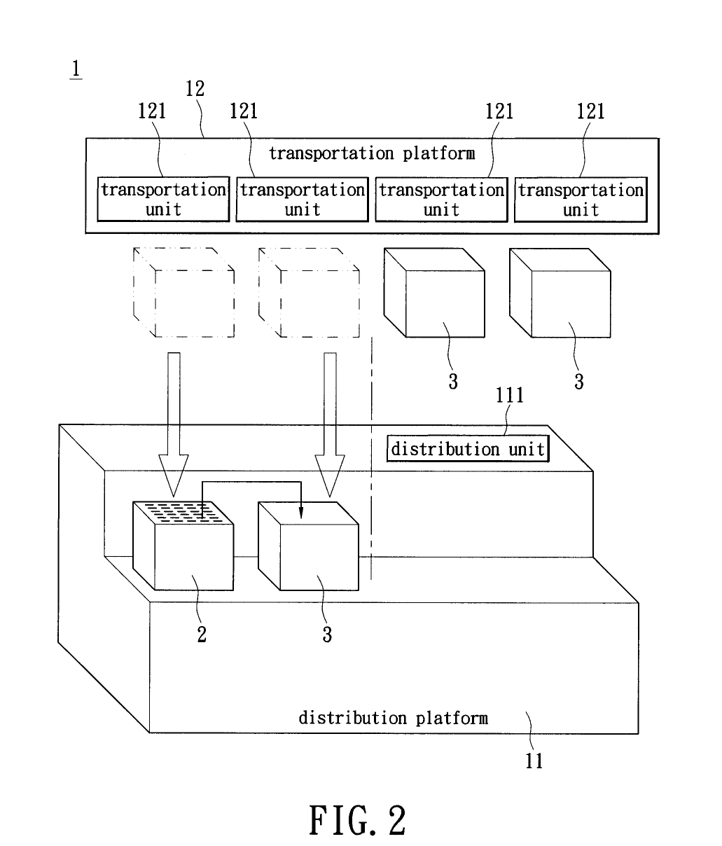

Reference is made to FIG. 2. The product distribution system 1 is applied to the product distribution in the semiconductor field. The product distribution system 1 includes a distribution platform 11 and a transportation platform 12. The distribution platform 11 is used for temporarily being placing with a main storage unit 2 and a secondary storage unit 3. The transportation platform 12 is used for transporting the main storage unit 2 and the secondary storage unit 3.

The distribution platform 11 has a distribution unit 11, and the distribution unit 111 is used for executing a distribution operation. The distribution operation is based on the product quantity stored in the secondary storage unit 3. The distribution unit 111 distributes the products in the main storage unit 2 into the secondary storage unit 3. The distribution unit 111 is a wafer sorter. The main storage unit 2 and the secondary storage unit 3 can be a cassette, a boat, a front opening unified pod (FOUP), or a front opening shipping box (FOSB). The product is a wafer. When the main storage unit 2 and the secondary storage unit 3 are located on the distribution platform 11, the distribution unit 111 of the distribution platform 11 starts to execute the distribution operation and distributes the wafer stored in the main storage unit 2 into the secondary storage unit 3. The main storage unit 2 and the secondary storage unit 3 is not limited to a cassette, a boat, a front opening unified pod (FOUP), or a front opening shipping box (FOSB). The devices that can receive the wafer can be the main storage unit 2 and the secondary storage unit 3.

The transportation platform 12 has a plurality of transportation units 121. The transportation units 121 are used for transporting the main storage unit 2 and the secondary storage unit 3. In detail, the transportation unit 121 either transports the main storage unit 2 and the secondary storage unit 3 to the distribution platform 11, or transports the main storage unit 2 and the secondary storage unit 3 out of the distribution platform 11. The transportation unit 121 can be an overhead hoisting transport (OHT), an overhead hoist shuttle (OHS), a rail guided vehicle (RGV), or a stocker (STK). In this embodiment, the transportation unit 121 is an overhead hoist shuttle (OHS). However, the transportation unit 121 is not limited to above, and the device that can transport the main storage unit 2 and the secondary storage unit 3 can be the transportation unit 121.

Moreover, after the distribution unit 111 of the distribution platform 11 executes the distribution operation, which means that the quantity of the product for the secondary storage unit 3 is enough, so the transportation unit 121 of the transportation platform 12 removes the secondary storage unit 3, and transports another secondary storage unit 3 to the distribution platform 11, so that the distribution unit 111 of the distribution platform 11 may execute the distribution operation again.

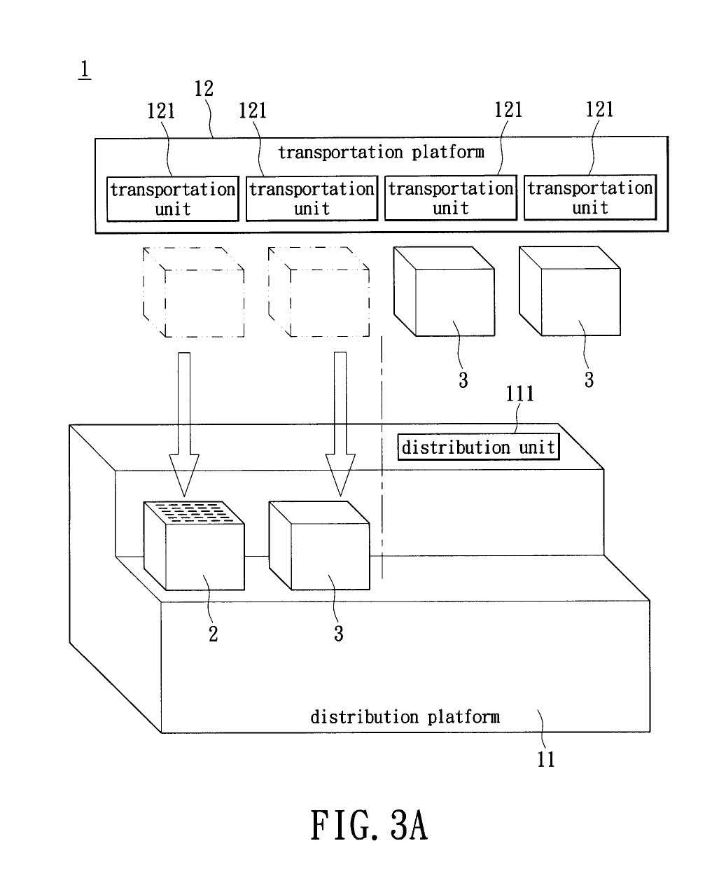

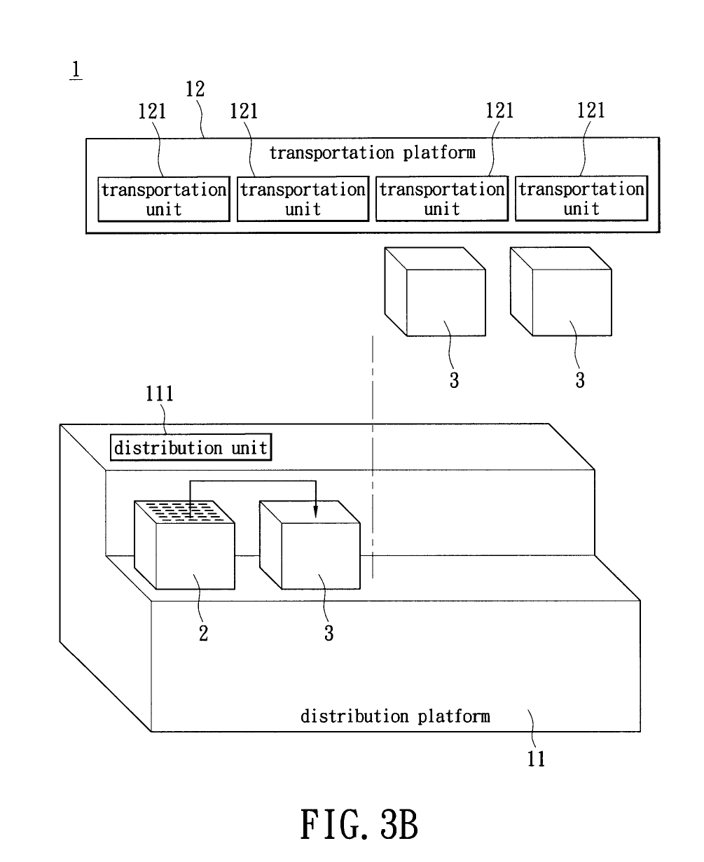

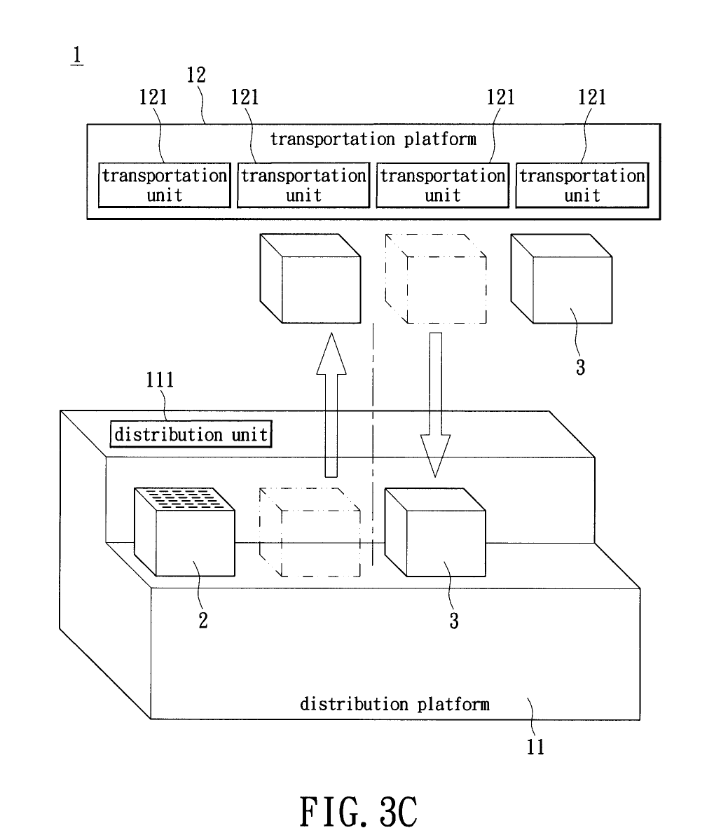

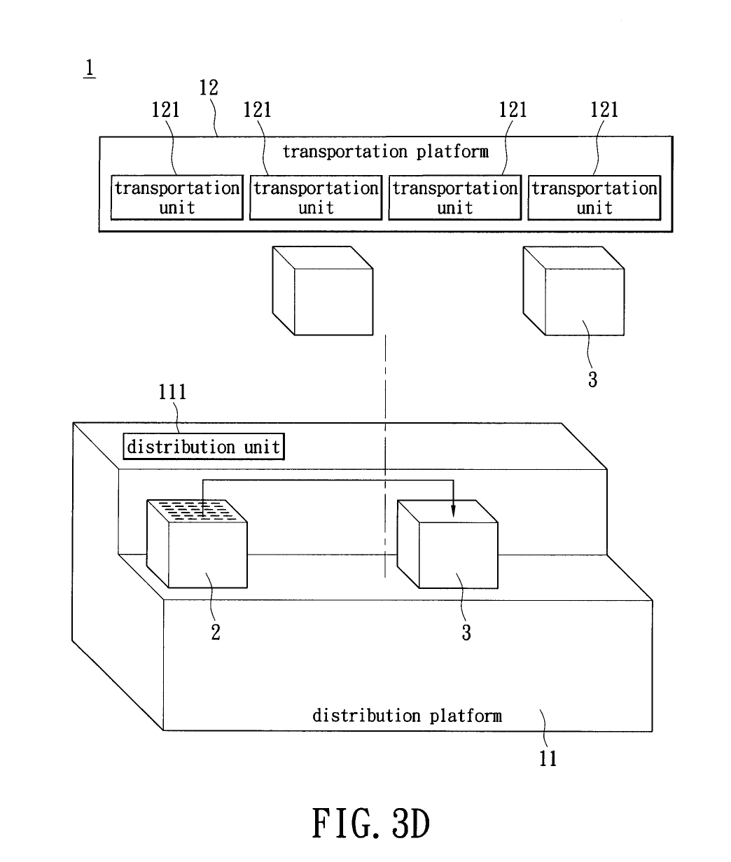

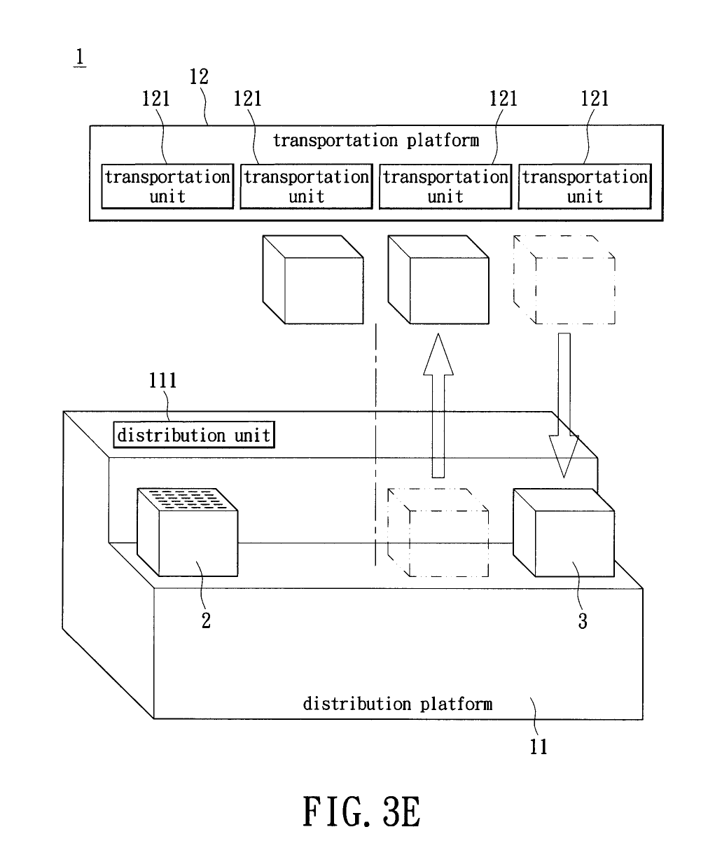

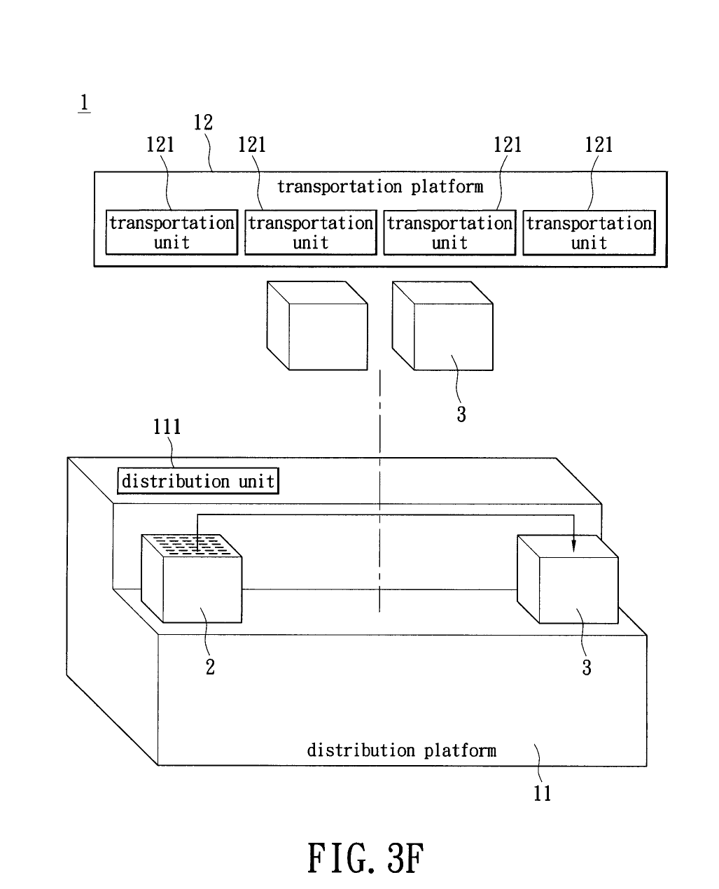

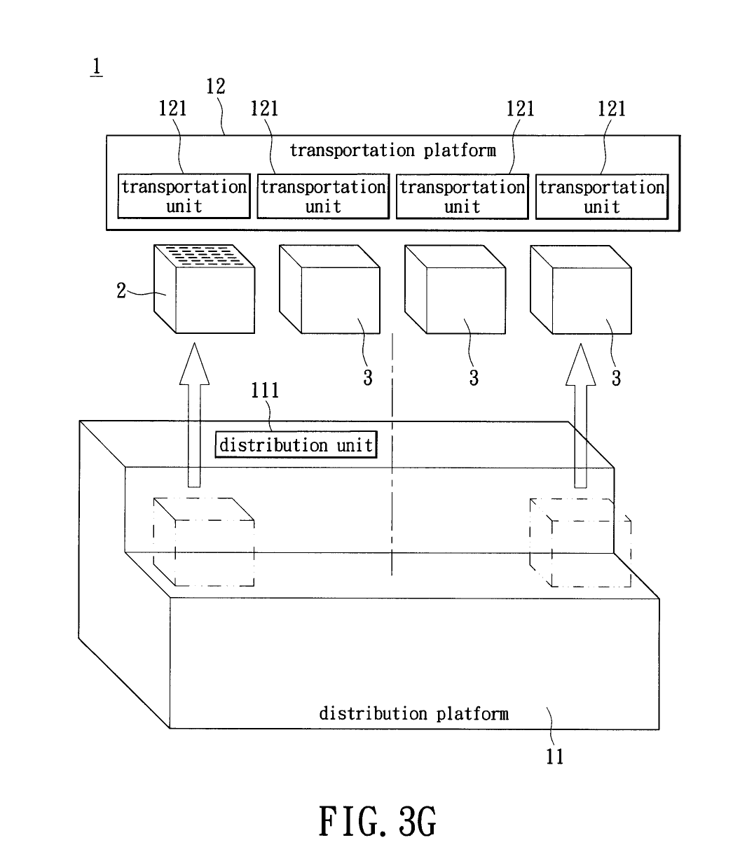

Reference is made to FIGS. 3A-3G. FIG. 3A-3G are schematic diagrams of the usage statuses of the automatic product distribution system of the present invention. The thin arrow represents the wafer distribution operation, and the empty-hearted arrow represents the transportation operation. First, the transportation unit 121 of the transportation platform 12 transports the main storage unit 2 and the secondary storage unit 3 to the distribution platform 11. When the main storage unit 2 and the secondary storage unit 3 are placed on the distribution platform 11, the distribution unit 111 of the distribution platform 11 executes the distribution operation. The distribution unit 111 distributes the products in the main storage unit 2 into the secondary storage unit 3 according to the required quantity of the secondary storage unit 3. When the quantity of the products in the secondary storage unit 3 is met, the transportation unit 121 of the transportation platform 12 removes the secondary storage unit 3 from the distribution platform 11, and transports another secondary storage unit 3 to the distribution platform 11 so that the distribution unit 111 of the distribution platform 11 executes the distribution operation again. In other words, the products in the main storage unit 2 are distributed to the secondary storage unit 3 again. Thereby, the above processes are repeated until all products in the main storage unit 2 are distributed. The transportation unit 121 of the transportation platform 12 removes the main storage unit 2 and the secondary storage unit 3 from the distribution platform 11. The order of the secondary storage units 3 being transported to the distribution platform 11 is not fixed. In detail, when one of the secondary storage units 3 is transported to the distribution platform 11, the distribution unit 111 of the distribution platform 11 executes the distribution operation to distribute the products in the main storage unit 2 into the secondary storage unit 3. When merely one main storage unit 2 and one secondary storage unit 3 are placed on the distribution platform 11, the distribution unit 111 starts to execute the distribution operation.

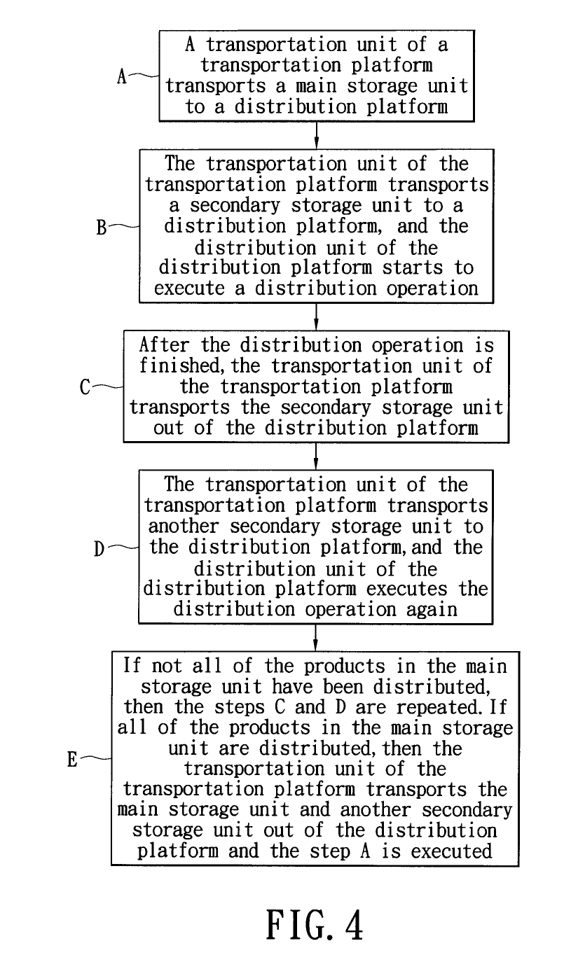

Reference is made to FIGS. 4, and 3A-3G. FIG. 4 is a flow chart of the product distribution method for the product distribution system 1 according to the present invention. The product distribution method includes the following steps.

A. The transportation unit 121 of the transportation platform 12 transports the main storage unit 2 to the distribution platform 11. The main storage unit 2 is stored with products. The product is a wafer.

B. After the main storage unit 2 is temporarily placed on the distribution platform 11, the transportation unit 121 of the transportation platform 12 transports the secondary storage unit 3 to the distribution platform 11. When the main storage unit 2 and the secondary storage unit 3 are temporarily placed on the distribution platform 11, the distribution unit 111 of the distribution platform 11 starts to execute the distribution operation. The main storage unit 2 and the secondary storage unit 3 can be a cassette, a boat, a front opening unified pod (FOUP), or a front opening shipping box (FOSB).

C. After the distribution unit 111 of the distribution platform 11 finishes the distribution operation, the transportation unit 121 of the transportation platform 12 removes the secondary storage unit 3 from the distribution platform 11. The distribution operation is that the distribution unit 111 distributes the products in the main storage unit 2 into the secondary storage unit 3 according to the required quantity of the secondary storage unit 3.

D. Next, the transportation unit 121 of the transportation platform 12 transports another secondary storage unit 3 to the distribution platform 11. When the distribution platform 11 is temporarily stored with the main storage unit 2 and another secondary storage unit 3, the distribution unit 111 of the distribution platform 11 executes the distribution operation again.

F. Finally, when all of the products in the main storage unit 2 are not distributed, the steps C and D are repeated. When the all of the products in the main storage unit 2 are distributed, the transportation unit 121 of the transportation platform 12 removes the main storage unit 2 and another secondary storage unit 3 from the distribution platform 11, and the step A is executed.

The transportation platform 12 is used for transporting the main storage unit 2 and the secondary storage unit 3. The transportation unit 121 either transports the main storage unit 2 and the secondary storage unit 3 to the distribution platform 11, or transports the main storage unit 2 and the secondary storage unit 3 out of the distribution platform 11. The transportation unit 121 can be an overhead hoisting transport (OHT), an overhead hoist shuttle (OHS), a rail guided vehicle (RGV), or a stocker (STK) for transporting the main storage unit 2 and the secondary storage unit 3

The automatic product distribution system and the product distribution method of the present invention have the following characteristics.

1. The automatic product distribution system and the product distribution method can reduce the time of the main storage unit 2 and the secondary storage unit 3 being idle on the distribution platform 11 and thereby improve the production speed.

2. For the automatic product distribution system and the product distribution method, the distribution platform 11 can execute the distribution operation when merely one main storage unit 2 and one secondary storage unit 3 are placed on the distribution platform 11. It does not need to transport all of the secondary storage units 3 to the distribution platform 11. Therefore, the present invention can continuously perform the distribution operation, and the idle problem is solved.

The description above only illustrates specific embodiments and examples of the present invention. The present invention should therefore cover various modifications and variations made to the herein-described structure and operations of the present invention, provided they fall within the scope of the present invention as defined in the following appended claims.

What is claimed is:

1. An automatic product distribution system, applied to a product distribution in a semiconductor foundry to distribute products in a main storage unit to a secondary storage unit, comprising:
a distribution platform for temporarily being placed with the main storage unit and the secondary storage unit, wherein the distribution platform has a distribution unit, and the distribution unit distributes the products in the main storage unit into the secondary storage unit; and
a transportation platform for transporting the main storage unit and the secondary storage unit, wherein after the distribution unit executes a distribution operation, the transportation platform moves the secondary storage unit out of the distribution platform.

2. The automatic product distribution system as claimed in claim 1, wherein the main storage unit and the secondary storage unit are a cassette, a boat, a front opening unified, or a front opening shipping box.

3. The automatic product distribution system as claimed in claim 1, wherein the product is a wafer.

4. The automatic product distribution system as claimed in claim 1, wherein the distribution unit is a wafer sorter.

5. The automatic product distribution system as claimed in claim 1, wherein the transportation platform further has a plurality of transportation units, and the transportation unit either transports the main storage unit and the secondary storage unit to the distribution platform or removes the main storage unit and the secondary storage unit from the distribution platform.

6. The automatic product distribution system as claimed in claim 5, wherein the transportation unit is an overhead hoisting transport, an overhead hoist shuttle, a rail guided vehicle, or a stocker.

7. The automatic product distribution system as claimed in claim 1, wherein the distribution operation is to distribute the products in the main storage unit to the secondary storage unit according to the quantity of the products stored in the secondary storage unit.

8. A product distribution method of the automatic product distribution system as claimed in claim 1, comprising:
transporting the main storage unit to the distribution platform;
transporting the secondary storage unit to the distribution platform and executing the distribution operation by the distribution unit;
after the distribution operation is finished, if the products in the main storage unit are not all distributed, then the secondary storage unit is transported out of the distribution platform and another secondary storage unit is transported to the distribution platform, and the distribution unit executes the distribution operation again; and
if the products in the main storage unit are all distributed, then the transportation platform transports the main storage unit and the secondary storage unit out of the distribution platform.

9. The product distribution method as claimed in claim 8, wherein the main storage unit and the secondary storage unit are a cassette, a boat, a front opening unified, or a front opening shipping box.

10. The product distribution method as claimed in claim 8, wherein the product is a wafer.

11. The product distribution method as claimed in claim 8, wherein the distribution unit is a wafer sorter.

12. The product distribution method as claimed in claim 8, wherein the distribution operation is to distribute the products in the main storage unit to the secondary storage unit according to the quantity of the products stored in the secondary storage unit.

13. The product distribution method as claimed in claim 8, wherein the transportation platform further has a plurality of transportation units, and the transportation unit is used for transporting the main storage unit and the secondary storage unit.

14. The automatic product distribution system as claimed in claim 13, wherein the transportation unit is an overhead hoisting transport, an overhead hoist shuttle, a rail guided vehicle, or a stocker.
